(19) United States
(12) Patent Application Publication
(10) Pub. No.: US 2022/0149806 A1
(43) Pub. Date: May 12, 2022

(54) BULK ACOUSTIC WAVE RESONATOR

(71) Applicant: SAMSUNG ELECTRO-MECHANICS CO., LTD., Suwon-si (KR)

(72) Inventors: Tae Kyung LEE, Suwon-si (KR); Sang Heon HAN, Suwon-si (KR); Sung Joon PARK, Suwon-si (KR); Sang Kee YOON, Suwon-si (KR); Sang Hyun YI, Suwon-si (KR); Jae Goon AUM, Suwon-si (KR)

(73) Assignee: SAMSUNG ELECTRO-MECHANICS CO., LTD., Suwon-si (KR)

(21) Appl. No.: 17/226,317

(22) Filed: Apr. 9, 2021

(30) Foreign Application Priority Data
Nov. 9, 2020 (KR) 10-2020-0148324

(51) Int. Cl. H03H 9/02; H03H 9/17

(52) U.S. Cl. CPC H03H 9/02102; H03H 9/175; H03H 9/173

(57) ABSTRACT

A bulk acoustic wave resonator includes: a substrate; a resonant portion including a first electrode, a piezoelectric layer, and a second electrode sequentially stacked on the substrate; and a protective layer disposed on an upper surface of the resonant portion. The protective layer includes: a first protective layer formed of a diamond thin film; and a second protective layer stacked on the first protective layer, and formed of a dielectric material.

### CROSS-REFERENCE TO RELATED APPLICATIONS

This application claims the benefit under 35 U.S.C. § 119(a) of Korean Patent Application No. 10-2020-0148324 filed on Nov. 9, 2020 in the Korean Intellectual Property Office, the entire disclosure of which is incorporated herein by reference for all purposes.

### BACKGROUND

### 1. Field

The following description relates to a bulk acoustic wave resonator.

### 2. Description of Related Art

In accordance with the trend for miniaturization of wireless communications devices, there has been a demand for miniaturization of high frequency component technology. As an example, bulk acoustic wave (BAW) resonator-type filters using semiconductor thin film wafer manufacturing technology have been implemented in wireless communication devices.

A bulk acoustic wave (BAW) resonator is a thin film-type element configured to generate resonance using piezoelectric characteristics of a piezoelectric dielectric material deposited on a semiconductor substrate, such as a silicon wafer, and may be implemented as a filter.

Recently, interest in 5G communications technology has increased, and technological development of a BAW resonator that may be implemented in a candidate band has been conducted. However, in a case of 5G communications using a sub-6 GHz (e.g., 4 to 6 GHz) frequency band, a bandwidth increases and a communications distance is shortened, such that a signal strength or power of the bulk acoustic wave resonator may increase.

When the power of the BAW resonator increases, a temperature of a resonant portion of the BAW resonator tends to increase linearly. Therefore, it is desirable to provide a BAW resonator in which heat generated in the resonant portion may be effectively dissipated.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic wave resonator includes: a substrate; a resonant portion including a first electrode, a piezoelectric layer, and a second electrode sequentially stacked on the substrate; and a protective layer disposed on an upper surface of the resonant portion. The protective layer includes: a first protective layer formed of a diamond thin film; and a second protective layer stacked on the first protective layer, and formed of a dielectric material.

A portion of the second protective layer may have a thickness greater than a thickness of the first protective layer.

The first protective layer may have a thickness of 500 Å or greater, and the second protective layer may have a thickness of 4000 Å or less.

The first electrode and the second electrode may extend outwardly of the resonant portion. A first metal layer may be disposed on the first electrode, outside the resonant portion, and a second metal layer may be disposed on the second electrode, outside the resonant portion. Portions of the first protective layer may be in contact with the first metal layer and the second metal layer.

Parts of the first protective layer may be disposed below the first metal layer and the second metal layer.

A thickness of the protective layer in a region in which the protective layer is disposed below the first metal layer and the second metal layer may be greater than a thickness of the protective layer in a region in which the protective layer is disposed on the resonant portion.

The second protective layer may include any one of silicon dioxide (SiO₂), silicon nitride (Si₃N₄), magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), zinc oxide (ZnO), amorphous silicon (a-Si), and polycrystalline silicon (p-Si).

The second electrode may include at least one opening. The first protective layer may be disposed in the at least one opening to be in direct contact with the piezoelectric layer.

The second electrode may include at least one opening. The piezoelectric layer is disposed in the at least one opening to be in direct contact with the second protective layer.

The bulk acoustic wave resonator may further include a support portion disposed below the piezoelectric layer and partially raising the piezoelectric layer so that a portion of the piezoelectric layer is disposed in the at least one opening.

The first protective layer may be formed of a material having thermal conductivity higher than thermal conductivity of the piezoelectric layer and thermal conductivity of the second electrode.

The bulk acoustic wave resonator may further include an insertion layer partially disposed in the resonant portion and disposed between the first electrode and the piezoelectric layer. At least a portion of the piezoelectric layer may be raised by the insertion layer.

The second electrode may include at least one opening. The insertion layer may include a support portion disposed in a region corresponding to a region of the at least one opening.

The insertion layer may have an inclined surface. The piezoelectric layer may include a piezoelectric portion disposed on the first electrode and an inclined portion disposed on the inclined surface.

The bulk acoustic wave resonator of claim 14, wherein, in a cross section of the resonant portion, a distal end of the second electrode is disposed on the inclined portion or is disposed along a boundary between the piezoelectric portion and the inclined portion.

The piezoelectric layer may include an extended portion disposed outside the inclined portion. At least a portion of the second electrode may be disposed on the extended portion.

The bulk acoustic wave resonator may further include a Bragg reflection layer disposed in the substrate. First reflection layers and second reflection layers may be alternately stacked in the Bragg reflection layer. The second reflection layers may have an acoustic impedance lower than an acoustic impedance of the first reflection layers.

A cavity having a groove shape may be formed in an upper surface of the substrate. The resonant portion may be spaced apart from the substrate by a predetermined distance by the cavity.

The diamond thin film may have an average grain size of 50 nm to 1 μm.

Other features and aspects will be apparent from the following detailed description, the drawings, and the claims.

### BRIEF DESCRIPTION OF DRAWINGS

FIG. 1 is a plan view of a bulk acoustic wave resonator, according to an embodiment.

FIG. 2 is a cross-sectional view taken along line I-I′ of FIG. 1.

FIG. 3 is a cross-sectional view taken along line II-II′ of FIG. 1.

FIG. 4 is a cross-sectional view taken along line III-III′ of FIG. 1.

FIG. 5 is a graph illustrating thermal conductivity of a diamond thin film according to a grain size of the diamond thin film.

FIG. 6 is a schematic cross-sectional view illustrating a bulk acoustic wave resonator, according to another embodiment.

FIG. 7 is a schematic cross-sectional view illustrating a bulk acoustic wave resonator, according to another embodiment.

FIG. 8 is a schematic cross-sectional view illustrating a bulk acoustic wave resonator, according to another embodiment.

FIG. 9 is a schematic cross-sectional view illustrating a bulk acoustic wave resonator, according to another embodiment.

FIG. 10 is a schematic cross-sectional view illustrating a bulk acoustic wave resonator, according to another embodiment.

FIG. 11 is a schematic cross-sectional view illustrating a bulk acoustic wave resonator, according to another embodiment.

FIG. 12 is a schematic cross-sectional view illustrating a bulk acoustic wave resonator, according to another embodiment.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure. Hereinafter, while embodiments of the present disclosure will be described in detail with reference to the accompanying drawings, it is noted that examples are not limited to the same.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. As used herein “portion” of an element may include the whole element or less than the whole element.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may be also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

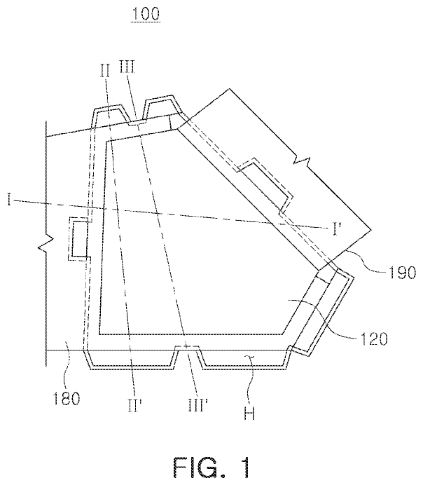

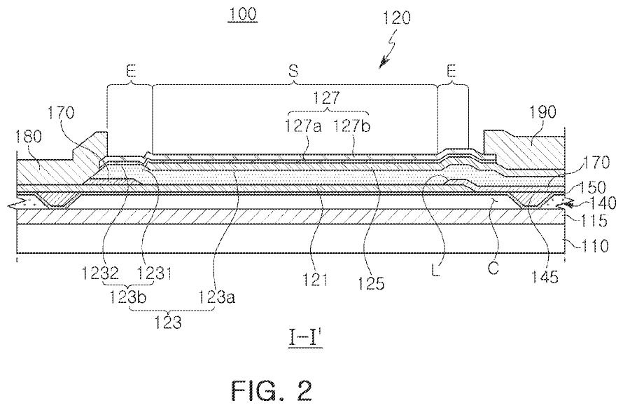

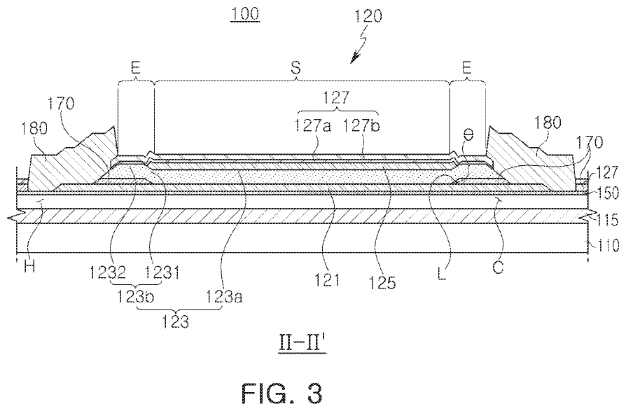

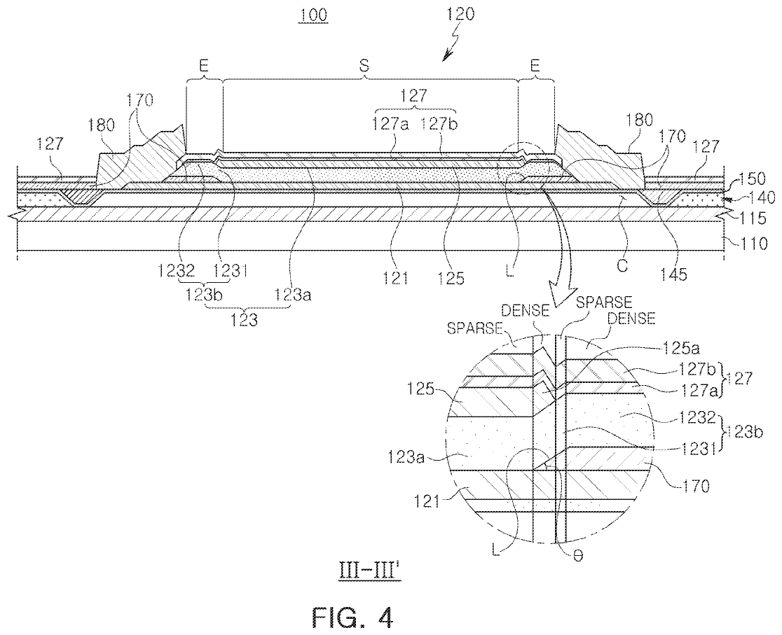

FIG. 1 is a plan view of a bulk acoustic wave resonator 100, according to an embodiment. FIG. 2 is a cross-sectional view taken along line I-I′ of FIG. 1. FIG. 3 is a cross-sectional view taken along line II-II′ of FIG. 1. FIG. 4 is a cross-sectional view taken along line III-III′ of FIG. 1.

Referring to FIGS. 1 through 4, the bulk acoustic resonator (or acoustic resonator) 100 may include, for example, a substrate 110, a support layer 140, a resonant portion 120, and an insertion layer 170.

The substrate 110 may be a silicon substrate. For example, a silicon wafer or a silicon on insulator (SOI) type substrate may be used as the substrate 110.

An insulating layer 115 may be provided on an upper surface of the substrate 110 to electrically isolate the substrate 110 and the resonant portion 120 from each other. In addition, the insulating layer 115 may prevent the substrate 110 from being etched by an etching gas at the time of forming a cavity C in a process of manufacturing the acoustic resonator.

The insulating layer 115 may be formed of any one or any combination of any two or more of silicon dioxide (SiO₂), silicon nitride (Si₃N₄), aluminum oxide (Al₂O₃), and aluminum nitride (AlN), and may be formed by any one of a chemical vapor deposition process, a radio frequency (RF) magnetron sputtering process, and an evaporation process.

The support layer 140 may be formed on the insulating layer 115, and may be disposed around a cavity C and an etching preventing portion 145 so as to surround the cavity C and the etching preventing portion 145 inside the support layer 140.

The cavity C may be formed as an empty space and may be formed by removing a portion of a sacrificial layer formed in a process of preparing the support layer 140. The support layer 140 may be formed as a remaining portion of the sacrificial layer.

The support layer 140 may be formed of a material such as polysilicon or a polymer that may be easily etched. However, the material of the support layer 140 is not limited to the aforementioned examples.

The etching preventing portion 145 may be disposed along a boundary of the cavity C. The etching preventing portion 145 may be provided in order to prevent etching from being performed beyond a cavity region in a process of forming the cavity C.

A membrane layer 150 may be formed on the support layer 140, and may form an upper surface of the cavity C. Therefore, the membrane layer 150 may also be formed of a material not easily removed in the process of forming the cavity C.

For example, when a halide based etching gas, such as fluorine (F) or chlorine (CI), is used to remove a part (for example, a cavity region) of the support layer 140, the membrane layer 150 may be formed of a material of which reactivity to the abovementioned etching gas is low. The membrane layer 150 may include either one or both of silicon dioxide (SiO₂) and silicon nitride (Si₃N₄).

In addition, the membrane layer 150 may be a dielectric layer containing any one or any combination of any two or more of magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), and zinc oxide (ZnO), or be a metal layer containing any one or any combination of any two or more of aluminum (Al), nickel (Ni), chromium (Cr), platinum (Pt), gallium (Ga), and hafnium (Hf). However, the membrane layer 150 is not limited to the aforementioned examples.

The resonant portion 120 may include a first electrode 121, a piezoelectric layer 123, and a second electrode 125. In the resonant portion 120, the first electrode 121, the piezoelectric layer 123, and the second electrode 125 may be sequentially stacked from a lower portion of the resonant portion 120. Therefore, in the resonant portion 120, the piezoelectric layer 123 may be disposed between the first electrode 121 and the second electrode 125.

Since the resonant portion 120 is formed on the membrane layer 150, the membrane layer 150, the first electrode 121, the piezoelectric layer 123, and the second electrode 125 may be sequentially stacked on the substrate 110 to form the resonant portion 120.

The resonant portion 120 may resonate the piezoelectric layer 123 according to signals applied to the first electrode 121 and the second electrode 125 to generate a resonant frequency and an anti-resonant frequency.

The resonant portion 120 may include a central portion S in which the first electrode 121, the piezoelectric layer 123, and the second electrode 125 are approximately flatly stacked and an extension portion E in which the insertion layer 170 is interposed between the first electrode 121 and the piezoelectric layer 123.

The central portion S may be a region disposed at the center of the resonant portion 120, and the extension portion E may be a region disposed along a circumference of the central portion S. Therefore, the extension portion E, which is a region extending outwardly from the central portion S, may be a region formed in a continuous ring shape along the circumference of the central portion S. Alternatively, the extension portion E may be formed in a discontinuous ring shape of which some regions are disconnected, if necessary.

Therefore, as illustrated in FIG. 2, in a cross-section of the resonant portion 120 cut across the central portion S, the extension portion E may be disposed at both ends of the central portion S. In addition, the insertion layer 170 may be inserted into the extension portion E at both ends of the central portion S.

The insertion layer 170 may have an inclined surface L so as to have a thickness that becomes greater as a distance from the central portion S increases.

In the extension portion E, the piezoelectric layer 123 and the second electrode 125 may be disposed on the insertion layer 170. Therefore, the portions of the piezoelectric layer 123 and the second electrode 125 positioned in the extension portion E may have inclined surfaces according to a shape of the insertion layer 170.

In the embodiment of FIGS. 1 to 4, the extension portion E may be included in the resonant portion 120, and thus, resonance may also be generated in the extension portion E. However, a position at which the resonance is generated is not limited to this example. That is, the resonance may not be generated in the extension portion E according to a structure of the extension portion E, and may be generated only in the central portion S.

The first electrode 121 and the second electrode 125 may each be formed of a conductor, for example, gold, molybdenum, ruthenium, iridium, aluminum, platinum, titanium, tungsten, palladium, tantalum, chromium, or nickel, or a metal including any one or any combination of any two or more of gold, molybdenum, ruthenium, iridium, aluminum, platinum, titanium, tungsten, palladium, tantalum, chromium, and nickel. However, the first electrode 121 and the second electrode 125 are not limited to the foregoing examples.

In the resonant portion 120, the first electrode 121 may be formed to have an area greater than that of the second electrode 125, and a first metal layer 180 may be disposed along an outer side of the first electrode 121 on the first electrode 121. Therefore, the first metal layer 180 may be disposed to be spaced apart from the second electrode 125 by a predetermined distance, and may be disposed to surround the resonant portion 120.

The first electrode 121 may be disposed on the membrane layer 150, and may thus be entirely flat. The second electrode 125 may be disposed on the piezoelectric layer 123, and may thus have a bend formed to correspond to a shape of the piezoelectric layer 123.

The first electrode 121 may be configured as either one of an input electrode inputting an electrical signal such as a radio frequency (RF) signal and an output electrode outputting an electric signal.

The second electrode 125 may be disposed throughout an entirety of the central portion S, and may be partially disposed in the extension portion E. Therefore, the second electrode 125 may include a portion disposed on a piezoelectric portion 123a of a piezoelectric layer 123, to be described in more detail later, and a portion disposed on a bent portion 123b of the piezoelectric layer 123.

For example, the second electrode 125 may be disposed to cover the entirety of the piezoelectric portion 123a and a portion of an inclined portion 1231 of the piezoelectric layer 123. Therefore, a portion 125a of the second electrode 125 (see FIG. 4) disposed in the extension portion E may have an area smaller than that of an inclined surface of the inclined portion 1231, and the second electrode 125 may have an area smaller than that of the piezoelectric layer 123 in the resonant portion 120.

Therefore, as illustrated in FIG. 2, in the cross-section of the resonant portion 120 cut across the central portion S, a distal end of the second electrode 125 may be disposed in the extension portion E. In addition, at least a portion of the distal end of the second electrode 125 disposed in the extension portion E may be disposed to overlap the insertion layer 170. Here, the term “overlap” means that when the second electrode 125 is projected on a plane on which the insertion layer 170 is disposed, a shape of the second electrode 125 projected on the plane overlaps the insertion layer 170.

The second electrode 125 may be configured as either one of the input electrode inputting an electrical signal such as a radio frequency (RF) signal and the output electrode outputting an electric signal. That is, when the first electrode 121 is configured as the input electrode, the second electrode 125 may be configured as the output electrode, and, when the first electrode 121 is configured as the output electrode, the second electrode 125 may be configured as the input electrode.

As illustrated in FIG. 4, when the distal end of the second electrode 125 is positioned on the inclined portion 1231 of the piezoelectric layer 123, which will be described in more detail later, acoustic impedance of the resonant portion 120 may have a local structure formed in a sparse/dense/sparse/dense structure from the central portion S, and a reflection interface reflecting lateral waves inwardly of the resonant portion 120 may thus be increased. Therefore, most of the lateral waves may not escape outwardly of the resonant portion 120 and may be reflected inwardly in the resonant portion 120, and performance of the bulk acoustic resonator 100 may thus be improved.

The piezoelectric layer 123 may be a portion configured to generate a piezoelectric effect of converting electrical energy into mechanical energy having an elastic wave form, and may be formed on the first electrode 121 and the insertion layer 170, as will be described in more detail later.

Zinc oxide (ZnO), aluminum nitride (AlN), doped aluminum nitride, lead zirconate titanate, quartz, or the like, may be selectively used as a material of the piezoelectric layer 123. The doped aluminum nitride may further include a rare earth metal, a transition metal, or an alkaline earth metal. The rare earth metal may include any one or any combination of any two or more of scandium (Sc), erbium (Er), yttrium (Y), and lanthanum (La). The transition metal may include any one or any combination of any two or more of hafnium (Hf), titanium (Ti), zirconium (Zr), tantalum (Ta), and niobium (Nb). In addition, the alkaline earth metal may include magnesium (Mg).

When a content of elements doped in aluminum nitride (AlN) in order to improve piezoelectric characteristics is less than 0.1 at % in the piezoelectric layer 123, piezoelectric characteristics higher than those of aluminum nitride (AlN) may not be implemented, and when a content of elements doped in aluminum nitride (AlN) exceeds 30 at % in the piezoelectric layer 123, it is difficult to perform manufacture and composition control for deposition, such that a non-uniform phase may be formed.

Therefore, the content of elements doped in aluminum nitride (AlN) in the piezoelectric layer 123 may be in the range of 0.1 to 30 at %.

Aluminum nitride (AlN) doped with scandium (Sc) may be used as the material of the piezoelectric layer 123. In this case, a piezoelectric constant may be increased to increase Kₜ² of the bulk acoustic wave resonator 100.

The piezoelectric layer 123 may include the piezoelectric portion 123a disposed in the central portion S and the bent portion 123b disposed in the extension portion E.

The piezoelectric portion 123a may be a portion directly stacked on an upper surface of the first electrode 121. Therefore, the piezoelectric portion 123a may be interposed between the first electrode 121 and the second electrode 125, and may be formed to be flat together with the first electrode 121 and the second electrode 125.

The bent portion 123b may be a region extending outwardly from the piezoelectric portion 123a and positioned in the extension portion E.

The bent portion 123b may be disposed on the insertion layer 170, and may have an upper surface raised according to a shape of the insertion layer 170. Therefore, the piezoelectric layer 123 may be bent at a boundary between the piezoelectric portion 123a and the bent portion 123b, and the bent portion 123b may be raised according to a thickness and a shape of the insertion layer 170.

The bent portion 123b may include the inclined portion 1231 and an extended portion 1232.

The inclined portion 1231 may refer to a portion inclined along an inclined surface L of an insertion layer 170, to be described in more detail later. In addition, the extended portion 1232 may be a portion extending outwardly from the inclined portion 1231.

The inclined portion 1231 may be formed in parallel with the inclined surface L of the insertion layer 170, and an inclination angle of the inclined portion 1231 may be the same as an inclination angle of the inclined surface L of the insertion layer 170.

The insertion layer 170 may be disposed along a surface formed by the membrane layer 150, the first electrode 121, and the etching preventing portion 145. Therefore, the insertion layer 170 may be partially disposed in the resonant portion 120, and may be disposed between the first electrode 121 and the piezoelectric layer 123.

The insertion layer 170 may be disposed around the central portion S and support the bent portion 123b of the piezoelectric layer 123. Therefore, the bent portion 123b of the piezoelectric layer 123 may be divided into the inclined portion 1231 and the extended portion 1232 according to the shape of the insertion layer 170.

The insertion layer 170 may be disposed in a region except for the central portion S. For example, the insertion layer 170 may be disposed over the entirety of the region except for the central portion S or be disposed in a portion of the region except for the central portion S on the substrate 110.

The insertion layer 170 may have a thickness that becomes greater as a distance from the central portion S increases. Therefore, a side surface of the insertion layer 170 disposed adjacent to the central portion S may be formed as the inclined surface L having a predetermined inclination angle θ.

When the inclination angle θ of the inclined surface L of the insertion layer 170 is less than 5°, a thickness of the insertion layer 170 needs to be very small or an area of the inclined surface L needs to be excessively large in order to manufacture the insertion layer 170. Thus, it is substantially difficult to implement the inclined surface L to have the inclination angle θ less than 5°.

In addition, when the inclination angle θ of the inclined surface L of the insertion layer 170 is greater than 70°, an inclination angle of the portion of piezoelectric layer 123 or the second electrode 125 stacked on the insertion layer 170 may be greater than 70°. In this case, the portion of the piezoelectric layer 123 or the second electrode 125 stacked on the inclined surface L may be excessively bent, and a crack may thus occur in a bent portion.

Therefore, in an example, the inclination angle θ of the inclined surface L may be in a range of 5° to 70°.

The inclined portion 1231 of the piezoelectric layer 123 may be formed along the inclined surface L of the insertion layer 170, and may thus be formed at the same inclination angle as the inclined surface L. Therefore, the inclination angle of the inclination portion 1231 may also be in a range of 5° to 70°, similar to the inclined surface L. Such a configuration may also be similarly applied to the portion of the second electrode 125 stacked on the inclined surface L.

The insertion layer 170 may be formed of a dielectric material such as silicon dioxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), or zinc oxide (ZnO), but may be formed of a material different from that of the piezoelectric layer 123.

Alternatively, the insertion layer 170 may be formed of a metal. When the bulk acoustic wave resonator 100 is used for 5G communications, a large amount of heat may be generated in the resonant portion, and thus, the heat generated in the resonant portion 120 needs to be smoothly dissipated. To this end, the insertion layer 170 may be formed of an aluminum alloy material containing scandium (Sc).

The resonant portion 120 may be disposed to be spaced apart from the substrate 110 through the cavity C, which may be formed as the empty space.

The cavity C may be formed by supplying an etching gas (or an etchant) to introduction holes H (see FIGS. 1 and 3) in the process of manufacturing the bulk acoustic wave resonator 100, to remove a portion of the support layer 140.

Therefore, the cavity C may be formed as a space of which an upper surface (a ceiling surface) and side surfaces (wall surfaces) are formed by the membrane 150, and a bottom surface is formed by the substrate 110 or the insulating layer 115. The membrane layer 150 may be formed only on the upper surface (a ceiling surface) of the cavity C, according to the order of a manufacturing method.

A protective layer 127 may be disposed along a surface of the bulk acoustic wave resonator 100 to prevent the bulk acoustic wave resonator 100 from external impact. The protective layer 127 may be disposed along a surface formed by the second electrode 125 and the bent portion 123b of the piezoelectric layer 123.

The protective layer 127 may include a first protective layer 127a formed of a diamond thin film and a second protective layer 127b formed of a dielectric material.

The first protective layer 127a is formed of diamond, which has an excellent thermal conductivity. Diamond, which is a material formed by crystallization of carbon elements at a high temperature and a high pressure, has been known as a material having the highest thermal conductivity among several materials. A diamond crystal may have an excellent thermal conductivity of about 2000 W/m·K, and may be suitable as a material of an acoustic wave device because it has the highest speed of sound among known materials.

However, when diamond is implemented as a thin film rather than a crystal, there is a problem that the thermal conductivity is lowered. In addition, the thermal conductivity of the diamond tends to increase as a grain size of the diamond increases.

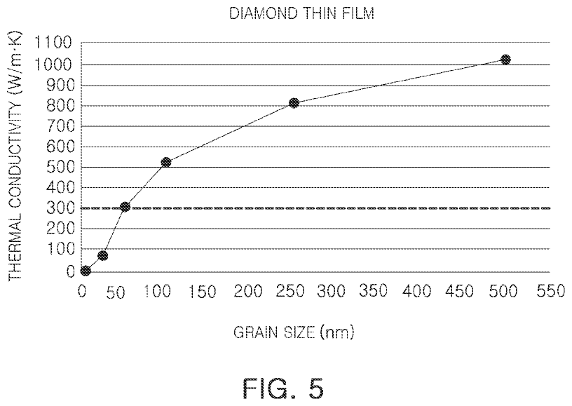

FIG. 5 is a graph illustrating thermal conductivity of a diamond thin film according to a grain size of the diamond thin film. Referring to FIG. 5, thermal conductivity of the diamond tends to increase as a grain size of the diamond increases.

The diamond may be thinned through chemical vapor deposition (CVD), and a degree of crystallinity of the diamond in a deposition process may determine the grain size.

It was confirmed that when an average grain size of the diamond thin film was 50 nm or more, the diamond thin film had thermal conductivity higher than that of the piezoelectric layer 123 formed of aluminum nitride (AlN) or the second electrode 125 formed of molybdenum (Mo). Specifically, when the average grain size of the diamond thin film was 50 nm or more, the thermal conductivity of the diamond thin film was measured to be 300 W/mk or more. In this case, it was confirmed that heat conduction was smoother than that of the piezoelectric layer 123 or the second electrode 125.

On the other hand, when the grain size of the diamond thin film is 1 ηm or more, as a surface roughness of the diamond thin film increases, scattering of sound waves may increase, and thus, the diamond thin film may not be suitable for being used for a bulk acoustic wave resonator.

Therefore, the average grain size of the diamond thin film in the bulk acoustic wave resonator 100 may be 50 nm to 1 μm.

When the diamond thin film was formed through chemical vapor deposition (CVD) as described above, it was confirmed that a thickness of the diamond thin film needs to be 500 Å or more in order for the diamond thin film to have the average grain size of 50 nm or more.

Therefore, in the bulk acoustic wave resonator 100, the first protective layer 127a may be formed to have a thickness of 500 Å or more.

As such, when the diamond thin film has the thermal conductivity higher than that of the piezoelectric layer 123 and the second electrode 125, heat generated in an active region of the resonant portion 120 may rapidly be dissipated through the first protective layer 127a formed of the diamond thin film, and a maximum temperature of the resonant portion 120 may thus be lowered.

Since the diamond thin film has a low etch rate, when the entire protective layer 127 is formed of the diamond thin film, it may be difficult to perform frequency trimming through the protective layer 127. Therefore, the protective layer 127 may include the second protective layer 127b stacked on the first protective layer 127a formed of the diamond thin film.

The second protective layer 127b may be disposed over the entirety of an upper surface of the first protective layer 127a. However, the second protective layer 127b is not limited to such a configuration.

The second protective layer 127b may be used for frequency trimming, and may thus be formed of a material suitable for the frequency trimming. For example, the second protective layer 127b may include any one of silicon dioxide (SiO₂), silicon nitride (Si₃N₄), magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), zinc oxide (ZnO), amorphous silicon (a-Si), and polycrystalline silicon (p-Si), but is not limited to the aforementioned examples.

At least a portion of the second protective layer 127b may be removed in a frequency trimming process. For example, a thickness of the second protective layer 127b may be controlled by frequency trimming in a manufacturing process.

At least a portion of the second protective layer 127b may be formed to have a thickness greater than that of the first protective layer 127a.

As a thickness of the protective layer 127 increases, a volume or a weight of the resonant portion 120 may increase, and Kₜ² of the bulk acoustic wave resonator 100 may thus decrease. In this case, Kₜ² may be increased by changing a thickness of the piezoelectric layer 123 or thicknesses of the first and second electrodes 121 and 125, which may increase a size or an area of the resonant portion 120.

Therefore, the thickness of the protective layer 127 needs to be limited in order to secure a required level of Kₜ² while maintaining the size and the area of the resonant portion 120.

Experimentally, when the thickness of the second protective layer 127b exceeded 4000 Å, the total thickness of the protective layer 127 exceeded 4500 Å. In this case, it was confirmed that the Kₜ² of the bulk acoustic wave resonator 100 was significantly decreased. Therefore, the second protective layer 127b may be formed to have a thickness of 4000 Å or less.

Therefore, the first protective layer 127a may be formed to have a thickness in a range of 500 Å or more and less than that of the second protective layer 127b, and the second protective layer 127b may be formed to have a thickness in a range of 4000 Å or less.

The first electrode 121 and the second electrode 125 may extend outwardly of the resonant portion 120. In addition, the first metal layer 180 and a second metal layer 190 may be disposed on upper surfaces of the portions of the first metal layer 180 and the second metal layer 190 that extend outwardly from the resonant portion 120, respectively.

The first metal layer 180 and the second metal layer 190 may each be formed of any one of gold (Au), a gold-tin (Au—Sn) alloy, copper (Cu), a copper-tin (Cu—Sn) alloy, aluminum (Al), and an aluminum alloy. The aluminum alloy may be an aluminum-germanium (Al—Ge) alloy or an aluminum-scandium (Al—Sc) alloy, for example.

The first metal layer 180 and the second metal layer 190 may function as connection wirings electrically connecting the first and second electrodes 121 and 125 of the bulk acoustic wave resonator 100 to electrodes of another bulk acoustic wave resonator disposed adjacent to the bulk acoustic wave resonator 100 on the substrate 110.

At least a portion of the first metal layer 180 may be in contact with the protective layer 127 and may be bonded to the first electrode 121.

In addition, in the resonant portion 120, the first electrode 121 may be formed to have an area greater than that of the second electrode 125, and the first metal layer 180 may be formed at a circumferential portion of the first electrode 121.

Therefore, the first metal layer 180 may be disposed along a circumference of the resonant portion 120, and may thus be disposed to surround the second electrode 125. However, the first metal layer 180 is not limited to the aforementioned configuration.

The first metal layer 180 and the second metal layer 190 may be formed of a metal having a high thermal conductivity and may have a large volume to have an excellent heat dissipation effect. Therefore, the first protective layer 127a may be connected to the first metal layer 180 and the second metal layer 190 so that so that heat generated in the piezoelectric layer 123 may rapidly be transferred to the first metal layer 180 and the second metal layer 190 via the first protective layer 127a.

At least portions of the first protective layer 127a may be disposed below the first metal layer 180 and the second metal layer 190. Specifically, the first protective layer 127a may be inserted between the first metal layer 180 and the piezoelectric layer 123 and between the second metal layer 190, and the second electrode 125 and the piezoelectric layer 123.

As described above, the first protective layer 127a may be formed of the diamond thin film. At least portions of the diamond thin film may be in direct contact with the first metal layer 180 and the second metal layer 190.

The bulk acoustic wave resonator 100 may show a temperature distribution in which a temperature is the highest in a center region of the resonant portion 120 and decreases from the center region of the resonant portion 120 toward an outer side, in the plan view illustrated in FIG. 1.

In the related art, a protective layer is formed of only one material, and SiO₂ and Si₃N₄ were mainly used as materials of the protective layer. SiO₂ and Si₃N₄ have a very low thermal conductivity, and thus, heat dissipation from the resonant portion 120 was not smoothly performed. For example, when the protective layer of the related art was formed of Si₃N₄, a maximum temperature in the center region of the resonant portion 120 was measured to be 179° C.

On the other hand, in a case in which the protective layer 127 included the diamond thin film, when the same power was applied to the resonant portion 120, a maximum temperature in the center region of the resonant portion 120 was measured to be 74° C., which was significantly lower than the maximum temperature described above. Therefore, it has been confirmed that heat is rapidly dissipated through the protective layer 127.

As described above, in the bulk acoustic wave resonator 100, the heat generated in the piezoelectric layer 123 may be transferred and dissipated to the first and second metal layers 180 and 190 through the first protective layer 127a having a relatively high thermal conductivity, such that a heat dissipation effect may be improved, and operational reliability of the bulk acoustic wave resonator 100 may be secured even though high power is applied to the resonant portion 120. Therefore, the bulk acoustic wave resonator 100 may be utilized as a bulk acoustic wave resonator suitable for 5G communications.

In addition, since the second protective layer 127b formed of a dielectric material is disposed on the first protective layer 127a, a heat dissipation effect may be improved through the protective layer 127, and the frequency trimming may be performed through the protective layer 127.

The present disclosure is not limited to the above-mentioned examples, and the above-mentioned examples may be modified in various ways.

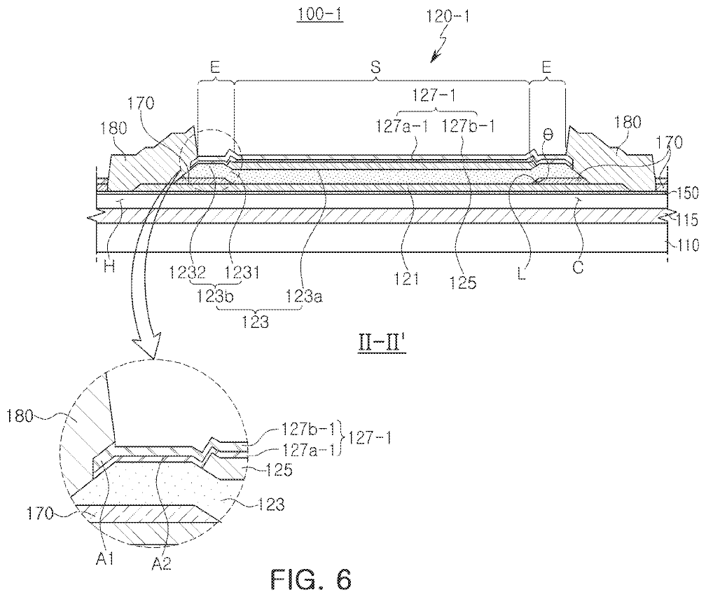

FIG. 6 is a schematic cross-sectional view illustrating a bulk acoustic wave resonator 100-1 having a resonant portion 120-1, according to another embodiment.

Referring to FIG. 6, in the bulk acoustic wave resonator 100-1, a protective layer 127-1 including a first protective layer 127a-1 and a second protective layer 127b-1 may have a first region A1 and a second region A2.

The first region A1 may be a region disposed below the first metal layer 180 or below the second metal layer 190 and having a thickness greater than that of the second region A2. The second region A2, which is a portion other than the first region A1, may be disposed in the resonant portion 120 and may have a thickness less than that of the first region A1.

Such a configuration may be implemented by forming the entire protective layer 127-1 to have a thickness of the first region A1 and then partially removing a portion of the second protective layer 127b-1 disposed in the second region A2. Therefore, at least a portion of the second protective layer 127b-1 may be formed to have a thickness greater than that of the first protective layer 127a-1. For example, the second protective layer 127b-1 may be formed to be thicker than the first protective layer 127a-1 in the first region A1, and thinner than the first protective layer 127a-1 in the second region A2. However, the second protective layer 127b-1 is not limited to such a configuration, and a portion or the entirety of the second protective layer 127b-1 may be formed to be thicker than the portion of first protective layer 127a-1 in the second region A2, if necessary.

As a thickness of the first protective layer 127a-1 formed of the diamond thin film increases, more grain growths may occur, and an effect of increasing the grain size may thus be obtained. Therefore, it may be advantageous in improving thermal conductivity of the first protective layer 127a-1 to keep the thickness of the first protective layer 127a-1 great.

Even though the first protective layer 127a-1 is described above as being configured to have a smaller thickness in the second region A2 than in the first region A1, the first protective layer 127a-1 may be formed to have the same thickness in both of the first region A1 and the second region A2, and thus may have a high thermal conductivity as a whole.

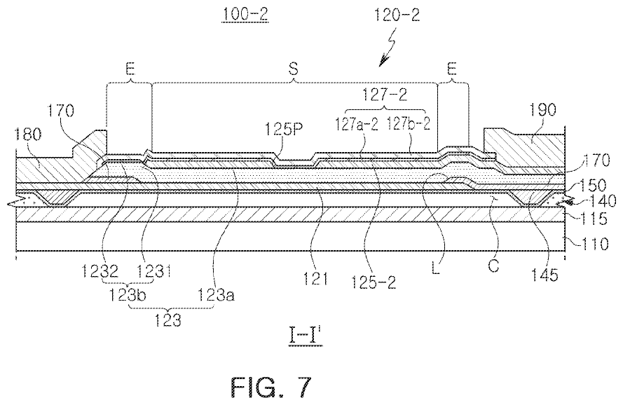

FIG. 7 is a schematic cross-sectional view illustrating a bulk acoustic wave resonator 100-2 having a resonant portion 120-2, according to another embodiment.

Referring to FIG. 7, a second electrode 125-2 may include at least one opening 125P. The opening 125P may be disposed at a central portion of the second electrode 125-2, a first protective layer 127a-2 of a protective layer 127-2 disposed on the second electrode 125 may be disposed in the opening 125P to be in direct contact with the piezoelectric layer 123, and a second protective layer 127b-2 of the protective layer 127-2 may be disposed on the first protective layer 127a-2 in the opening 125P.

The bulk acoustic wave resonator 100-2 may have a highest temperature at a central portion of the resonant portion 120-2 at a time of being operated. Therefore, if heat generated at the central portion of the resonant portion 120-2 may rapidly be dissipated, an entire temperature of the resonant portion 120-2 may be lowered.

Therefore, the bulk acoustic wave resonator 100-2 may be configured so that the piezoelectric layer 123, which is a heating element, is in direct contact with the first protective layer 127a-2 at the central portion of the resonant portion 120-2. In this case, heat generated in the piezoelectric layer 123 may be transferred directly to the first protective layer 127a-2 having a high thermal conductivity, and may thus be more effectively dissipated outwardly of the resonant portion 120-2. Therefore, a heat dissipation effect in the entire resonant portion 120-2 may be improved.

When an area of the opening 125P is 10% or more of an area of the resonant portion 120-2, a driving region of the resonant portion 120 may decrease, which may cause a decrease in Kₜ² and deterioration of insertion loss characteristics. Therefore, the area of the opening 125P may be 10% or less of the area of the resonant portion 120-2.

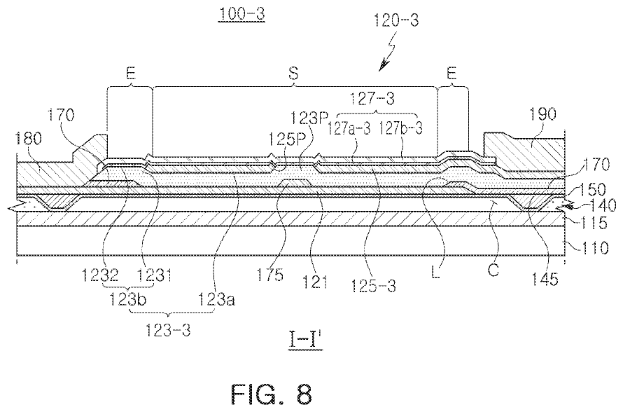

FIG. 8 is a schematic cross-sectional view illustrating a bulk acoustic wave resonator 100-3 including a resonant portion 120-3, according to another embodiment.

Referring to FIG. 8, a second electrode 125-3 may include the opening 125P formed at the central portion thereof. In addition, a piezoelectric layer 123-3 may be disposed in the opening 125P to be in direct contact with a first protective layer 127a-3 of a protective layer 127-3, and a second protective layer 127b-3 of the protective layer 127-3 may be disposed on the first protective layer 127a-3.

To this end, a support portion 175 may be disposed in a region corresponding to a region of the opening 125P below the piezoelectric layer 123-3. Here, the phrase “region corresponding to a region of the opening 125P” refers to a region overlapping a region of the opening 125P projected on a plane on which the insertion layer 170 is disposed when the opening 125P is projected on the plane.

The support portion 175 may be disposed at the lower portion of the piezoelectric layer 123-3 to partially raise the piezoelectric layer 123-3 and dispose the piezoelectric layer 123-3 in the opening 125P.

The piezoelectric layer 123-3 may include a raised portion 123P raised according to a shape of the support portion 175 and disposed in the opening 125P.

Side surfaces of the raised portion 123P may be formed as inclined surfaces, and the opening 125P of the second electrode 125-3 may be disposed along the inclined surfaces of the raised portion 123P. In this case, as illustrated in FIG. 8, end portions of the second electrode 125-3 in which the opening 125P is formed may be disposed on the inclined surfaces of the raised portion 123P.

Therefore, the entirety of an upper surface of the raised portion 123P may be configured to be in contact with the first protective layer 127a-3. In addition, parts of the inclined surfaces, which are the side surface of the raised portion 123P, may be configured to be in contact with the first protective layer 127a-3. However, the inclined surfaces are not limited the aforementioned configuration.

The support portion 175 may be configured as a portion of the insertion layer 170 described above. For example, in a process of forming the insertion layer 170, the support portion 175 may be formed of the same material as the insertion layer 170. However, the support portion 175 is not limited to this example, and may also be formed separately from the insertion layer 170. In this case, the support portion 175 may be formed of a material different from that of the insertion layer 170, but is not limited thereto.

In addition, a case where the support portion 175 is disposed between the first electrode 121 and the piezoelectric layer 123-3 has been described by way of example, but the support portion 175 may also be disposed between the membrane layer 150 and the first electrode 121, if necessary.

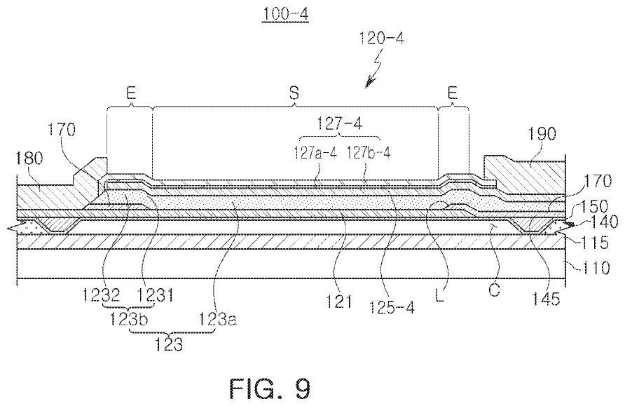

FIG. 9 is a schematic cross-sectional view illustrating a bulk acoustic wave resonator 100-4 including a resonant portion 120-4, according to another embodiment.

In the bulk acoustic wave resonator 100-4, a second electrode 125-4 may be disposed over the entirety of an upper surface of the piezoelectric layer 123 within the resonant portion 120-4. Therefore, the second electrode 125 may be formed on the extended portion 1232 of the piezoelectric layer 123 as well as on the inclined portion 1231 of the piezoelectric layer 123.

A protective layer 127-4 including a first protective layer 127a-4 and a second protective layer 127b-4 may be disposed on the second electrode 125-4.

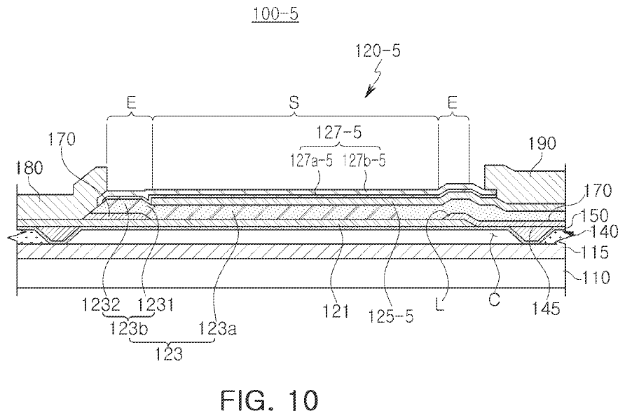

FIG. 10 is a schematic cross-sectional view illustrating a bulk acoustic wave resonator 100-5 including a resonant portion 120-5, according to another embodiment.

Referring to FIG. 10, in the bulk acoustic wave resonator 100-5, in a cross section of the resonant portion 120-5 cut across the central portion S, a distal end of a second electrode 125-5 may be formed only on an upper surface of the piezoelectric portion 123a of the piezoelectric layer 123, and may not be formed on the bent portion 123b of the piezoelectric layer 123. Therefore, the distal end of the second electrode 125-5 may be disposed along a boundary between the piezoelectric portion 123a and the inclined portion 1231.

A protective layer 127-5 including a first protective layer 127a-5 and a second protective layer 127b-5 may be disposed on the second electrode 125-5.

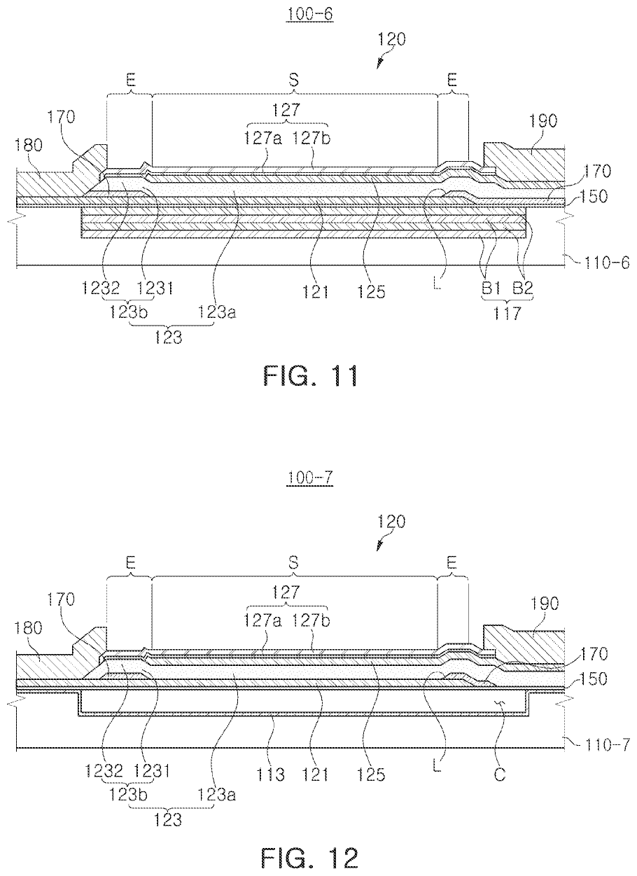

FIG. 11 is a schematic cross-sectional view illustrating a bulk acoustic wave resonator 100-6, according to another embodiment.

Referring to FIG. 11, the bulk acoustic wave resonator 100-6 may be formed similarly to the acoustic resonator 100 illustrated in FIGS. 2 and 3, but may not include the cavity C (see FIG. 2), and may include a Bragg reflection layer 117.

The Bragg reflection layer 117 may be disposed in a substrate 110-6 and may be formed by alternately stacking first reflection layers B1 having relatively high acoustic impedance and second reflection layers B2 having acoustic impedance lower than that of the first reflection layers B1 below the resonant portion 120.

In this case, the first reflection layer B1 and the second reflection layer B2 may have thicknesses defined according to a specific wavelength to reflect acoustic waves toward the resonant portion 120 in a vertical direction, thereby blocking the acoustic waves from flowing out downwardly from the substrate 110-6.

To this end, the first reflection layer B1 may be formed of a material having a density higher than that of the second reflection layer B2. For example, any one of W, Mo, Ru, Ir, Ta, Pt, and Cu may selectively be used as the material of the first reflection layer B1. In addition, the second reflection layer B2 may be formed of a material having a density lower than that of the first reflection layer B1. For example, any one of SiO₂, Si₃N₄, and AlN may selectively be used as the material of the second reflection layer B2. However, the materials of the first and second reflection layers are not limited to the foregoing examples.

FIG. 12 is a schematic cross-sectional view illustrating a bulk acoustic wave resonator 100-7, according to another embodiment.

Referring to FIG. 12, the bulk acoustic wave resonator 100-7 may be formed similarly to the acoustic resonator 100 illustrated in FIGS. 2 and 3, but the cavity C is not formed above a substrate 110-7, and may be formed by removing a portion of the substrate 110-7.

The cavity C may be formed by partially etching an upper surface of the substrate 110-7. Either one of dry etching and wet etching may be used to etch the substrate 110-7.

A barrier layer 113 may be formed on an inner surface of the cavity C. The barrier layer 113 may protect the substrate 110-7 from an etchant used in a process of forming the resonant portion 120.

The barrier layer 113 may be formed of a dielectric layer such as AlN or SiO₂, but is not limited thereto. That is, various materials may be used as the material of the barrier layer 113, as long as they may protect the substrate 110-7 from the etchant.

As described above, a bulk acoustic wave resonator according to the disclosure herein may be modified in various forms.

As set forth above, in a bulk acoustic wave resonator according to this disclosure, the heat generated in the piezoelectric layer may be transferred and dissipated to the first and second metal layers through the first protective layer having a relatively high thermal conductivity, and a heat dissipation effect may thereby be improved.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave resonator, comprising:
a substrate;
a resonant portion including a first electrode, a piezoelectric layer, and a second electrode sequentially stacked on the substrate; and
a protective layer disposed on an upper surface of the resonant portion,
wherein the protective layer includes:
a first protective layer formed of a diamond thin film; and
a second protective layer stacked on the first protective layer, and formed of a dielectric material.

2. The bulk acoustic wave resonator of claim 1, wherein a portion of the second protective layer has a thickness greater than a thickness of the first protective layer.

3. The bulk acoustic wave resonator of claim 1, wherein the first protective layer has a thickness of 500 Å or greater, and the second protective layer has a thickness of 4000 Å or less.

4. The bulk acoustic wave resonator of claim 1, wherein the first electrode and the second electrode extend outwardly of the resonant portion,
wherein a first metal layer is disposed on the first electrode, outside the resonant portion, and a second metal layer is disposed on the second electrode, outside the resonant portion, and
wherein portions of the first protective layer are in contact with the first metal layer and the second metal layer.

5. The bulk acoustic wave resonator of claim 4, wherein parts of the first protective layer are disposed below the first metal layer and the second metal layer.

6. The bulk acoustic wave resonator of claim 5, wherein a thickness of the protective layer in a region in which the protective layer is disposed below the first metal layer and the second metal layer is greater than a thickness of the protective layer in a region in which the protective layer is disposed on the resonant portion.

7. The bulk acoustic wave resonator of claim 1, wherein the second protective layer includes any one of silicon dioxide (SiO₂), silicon nitride (Si₃N₄), magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), zinc oxide (ZnO), amorphous silicon (a-Si), and polycrystalline silicon (p-Si).

8. The bulk acoustic wave resonator of claim 1, wherein the second electrode includes at least one opening, and
wherein the first protective layer is disposed in the at least one opening to be in direct contact with the piezoelectric layer.

9. The bulk acoustic wave resonator of claim 1, wherein the second electrode includes at least one opening, and
wherein the piezoelectric layer is disposed in the at least one opening to be in direct contact with the second protective layer.

10. The bulk acoustic wave resonator of claim 9, further comprising a support portion disposed below the piezoelectric layer and partially raising the piezoelectric layer so that a portion of the piezoelectric layer is disposed in the at least one opening.

11. The bulk acoustic wave resonator of claim 1, wherein the first protective layer is formed of a material having thermal conductivity higher than thermal conductivity of the piezoelectric layer and thermal conductivity of the second electrode.

12. The bulk acoustic wave resonator of claim 1, further comprising an insertion layer partially disposed in the resonant portion and disposed between the first electrode and the piezoelectric layer,
wherein at least a portion of the piezoelectric layer is raised by the insertion layer.

13. The bulk acoustic wave resonator of claim 12, wherein the second electrode includes at least one opening, and
wherein the insertion layer includes a support portion disposed in a region corresponding to a region of the at least one opening.

14. The bulk acoustic wave resonator of claim 12, wherein the insertion layer has an inclined surface, and
wherein the piezoelectric layer includes a piezoelectric portion disposed on the first electrode and an inclined portion disposed on the inclined surface.

15. The bulk acoustic wave resonator of claim 14, wherein, in a cross section of the resonant portion, a distal end of the second electrode is disposed on the inclined portion or is disposed along a boundary between the piezoelectric portion and the inclined portion.

16. The bulk acoustic wave resonator of claim 14, wherein the piezoelectric layer includes an extended portion disposed outside the inclined portion, and
wherein at least a portion of the second electrode is disposed on the extended portion.

17. The bulk acoustic wave resonator of claim 1, further comprising a Bragg reflection layer disposed in the substrate,
wherein first reflection layers and second reflection layers are alternately stacked in the Bragg reflection layer, and the second reflection layers have an acoustic impedance lower than an acoustic impedance of the first reflection layers.

18. The bulk acoustic wave resonator of claim 1, wherein a cavity having a groove shape is formed in an upper surface of the substrate, and
wherein the resonant portion is spaced apart from the substrate by a predetermined distance by the cavity.

19. The bulk acoustic wave resonator of claim 1, wherein the diamond thin film has an average grain size of 50 nm to 1 μm.
